(19) United States
(12) Patent Application Publication
(10) Pub. No.: US 2025/0118687 A1
(43) Pub. Date: Apr. 10, 2025

(54) SEMICONDUCTOR DEVICE

(71) Applicant: FUJI ELECTRIC CO., LTD., Kawasaki-shi (JP)

(72) Inventor: Daisuke ISOBE, Matsumoto-city (JP)

(73) Assignee: FUJI ELECTRIC CO., LTD., Kawasaki-shi (JP)

(21) Appl. No.: 18/820,170

(22) Filed: Aug. 29, 2024

(30) Foreign Application Priority Data
Oct. 4, 2023 (JP) 2023-172499

(51) Int. Cl. H01L 23/62; G01R 31/26; H01L 23/34

(52) U.S. Cl. CPC H01L 23/62; G01R 31/2601; G01R 31/2607; H01L 23/34

(57) ABSTRACT

A semiconductor device includes an output element, a temperature detection circuit, a current limiting circuit, and an overcurrent detection circuit. The output element is a power semiconductor element that drives a load, and is turned on by applying a predetermined turn-on voltage to a gate of the output element in a normal state. The temperature detection circuit detects the temperature of the output element as a detected temperature, during the operation of the output element. The overcurrent detection circuit detects an overcurrent state of the output element. When the overcurrent state is detected and the detected temperature exceeds a set temperature, the current limiting circuit sets a gate voltage of the output element to a set voltage lower than the predetermined turn-on voltage. In addition, the current limiting circuit increases the set voltage in stages as the temperature decreases.

### CROSS-REFERENCE TO RELATED APPLICATION

This application is based upon and claims the benefit of priority of the prior Japanese Patent Application No. 2023-172499, filed on Oct. 4, 2023, the entire contents of which are incorporated herein by reference.

### BACKGROUND OF THE INVENTION

### 1. Field of the Invention

The present disclosure discussed herein relates to a semiconductor device.

### 2. Background of the Related Art

A semiconductor device has been developed, which is obtained by integrating, in a single package, an output element using a power semiconductor element, a drive circuit for the output element, and a protection circuit and others peripheral to the output element. For example, such semiconductor devices are widely utilized in vehicle electrical systems such as transmissions, engines, and brakes, and there is a demand for products that achieve miniaturization, high performance, and high reliability.

As related art, there has been proposed a technique of changing an overcurrent detection threshold with a threshold control unit that is an internal circuit (International Publication Pamphlet No. WO 2021/125269). Further, there has been proposed a technique of performing on-off time control on the basis of a temperature detection signal during a hiccup operation, which is initiated when an overcurrent state is detected (Japanese Laid-open Patent Publication No. 2019-205300).

Still further, there has been proposed a technique of providing a plurality of voltage comparators that each output a comparison result signal on the basis of a result of comparing the charge voltage of a capacitor with a comparison voltage generated by a comparison voltage generation circuit (Japanese Laid-open Patent Publication No. 2013-062725). Yet still further, there has been proposed a detection circuit that provides a detection voltage having hysteresis characteristics and that includes an RS flip-flip that turns on and off according to an input voltage level against a threshold voltage (Japanese Laid-open Patent Publication No. H01-316668).

Yet still further, there has been proposed a technique in which an AND circuit that receives an output signal and a life end signal from an oscillator is connected to the set terminal of an RS flip-flop and a NOT circuit that receives the output signal is connected to the reset terminal thereof (Japanese Laid-open Patent Publication No. H08-098432). Yet still further, there has been proposed a technique in which a switch circuit is connected to the gate of a main MOS transistor and is configured to switch a gate current in a power switching element by controlling the on and off of the main MOS transistor (Japanese Laid-open Patent Publication No. 2015-195700). Yet still further, there has been proposed a gate drive circuit in which a plurality of gate charge extraction circuits with different resistances are arranged in parallel (Japanese Laid-open Patent Publication No. 2021-103849).

### SUMMARY OF THE INVENTION

According to one aspect, there is provided a semiconductor device, including: an output terminal connected to a load, and a power supply terminal connected to a power supply; an output element connected to the output terminal and to the power supply terminal, the output element being turned on by application of a predetermined turn-on voltage to a gate of the output element in a normal state; an overcurrent detection circuit configured to detect an overcurrent state of the output element; a temperature detection circuit configured to detect, as a detected temperature, a temperature of the output element during an operation of the output element using a reference temperature; and a current limiting circuit configured to limit a current flowing through the output element by setting a gate voltage of the output element to a set voltage lower than the predetermined turn-on voltage, in response to both detecting the overcurrent state and detecting that the detected temperature is equal to or higher than the set temperature, and increasing the set voltage in stages toward the predetermined turn-on voltage as the detected temperature decreases.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIGS. 1A and 1B are views for describing an example of the configuration and operation of a semiconductor device;

FIG. 2 illustrates an example of the configuration of the semiconductor device;

FIG. 3 illustrates an example of the configuration of a temperature detection circuit;

FIG. 4 illustrates an example of the configuration of a current limiting circuit;

FIG. 5 is a time chart representing an example of the operation of the current limiting circuit;

FIG. 6 illustrates an example of the configuration of a current limiting circuit;

FIG. 7 illustrates an example of the configuration of a temperature detection circuit;

FIG. 8 illustrates an example of the configuration of a current limiting circuit; and

FIG. 9 is a time chart representing an example of the operation of the current limiting circuit.

### DETAILED DESCRIPTION OF THE INVENTION

Hereinafter, an embodiment will be described with reference to the accompanying drawings. Note that the same reference numerals may be given to elements having substantially the same functions throughout the specification and drawings so as to omit the overlapping description.

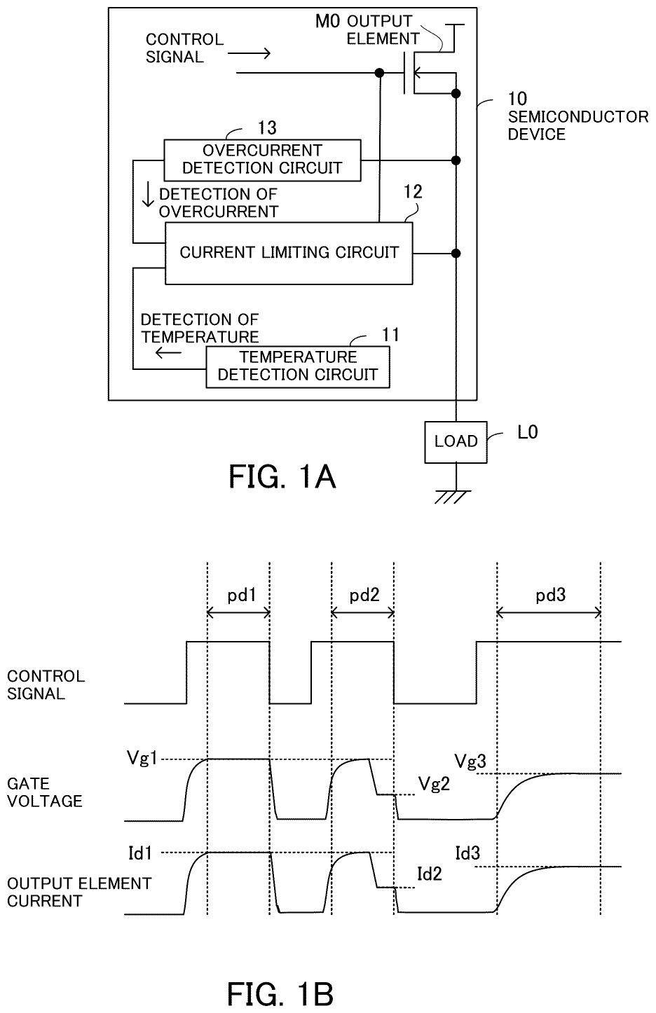

FIGS. 1A and 1B are views for describing an example of the configuration and operation of a semiconductor device. The configuration of the semiconductor device 10 will be described with reference to FIG. 1A. The semiconductor device 10 includes an output element M0, a temperature detection circuit 11, a current limiting circuit 12, and an overcurrent detection circuit 13. The output element M0 is a power semiconductor switching element that drives a load L0. The output element M0 is connected to the load L0, and drives the load L0 by performing switching.

A voltage-controlled switching element may be used as the output element M0. As an example, an N-channel metal-oxide-semiconductor field-effect transistor (MOSFET) is used as illustrated in FIG. 1A. Alternatively, an insulated gate bipolar transistor (IGBT) may be used in place of such a MOS transistor.

The temperature detection circuit 11 detects the temperature of the output element M0 during the operation of the output element M0. The overcurrent detection circuit 13 detects an overcurrent state of the output element M0.

In the case where the overcurrent state is detected and the detected temperature exceeds a set temperature, the current limiting circuit 12 sets the gate voltage of the output element M0 to a voltage lower than a voltage of when the temperature does not exceed the set temperature, to thereby limit a current flowing through the output element M0. In addition, the current limiting circuit 12 increases the gate voltage as the temperature decreases below the set temperature.

The operation of the semiconductor device 10 will be described with reference to FIG. 1B. It is assumed in FIG. 1B that the load L0 becomes short-circuited and this causes the overcurrent state.

Period pd1: An H-level control signal is input to the gate of the output element M0, so that the output element M0 is turned on. At this time, the gate voltage of the output element M0 is a turn-on voltage Vg1, and a current (output element current: drain current) flowing through the output element M0 is a current Id1.

Period pd2: An H-level control signal is input after the output element M0 is turned off at the end of the period pd1, so that the output element M0 is turned on. Assume that the load L0 is short-circuited and the overcurrent state is occurring, as described above, and that the temperature of the output element M0 exceeds the set temperature in the period pd2.

In this case, the current limiting circuit 12 sets the gate voltage of the output element M0 to a voltage Vg2 lower than the turn-on voltage Vg1 of the output element M0 (Vg2<Vg1). Therefore, the current flowing through the output element M1 decreases to a current Id2 lower than the current Id1 (Id2<Id1).

Period pd3: An H-level control signal is input after the output element M0 is turned off at the end of the period pd2, so that the output element M0 is turned on. Assume that the load L0 is repeatedly short-circuited and therefore the overcurrent state is occurring, but the temperature of the output element M0 has decreased below the set temperature.

In this case, the current limiting circuit 12 increases the gate voltage of the output element M0 to a voltage Vg3 higher than the voltage Vg2 (Vg2<Vg3<Vg1). Therefore, the current flowing through the output element M0 increases to a current Id3 higher than the current Id2 (Id2<Id3<Id1).

As a requirement for assuring the reliability of an output element, there is a demand for a technique that ensures a continued operation of the output element without a failure even when a load driven by the output element continues to be short-circuited (for example, the reliability standards AEC-Q-100 for automotive products define a test procedure for a continued operation in a short-circuit state). In this connection, in the case where a continuous flow of high current due to a short circuit has increased the temperature of the output element, even a circuit operation to interrupt or limit the overcurrent may lead to a reliability failure such as electromigration.

In a previous technique, when a load becomes short-circuited, an overcurrent detection circuit is activated to interrupt or limit a current flowing through an output element, and then if the overcurrent state repeatedly occurs and therefore the temperature of the output element increases, an overheat protection circuit is activated to interrupt the current flowing through the output element. However, since the overcurrent due to the short circuit flows while the output element whose temperature is around the operating temperature of the overheat protection circuit operates, the output element is continuously subjected to high temperature and high current stress, which may induce an electromigration phenomenon.

To avoid such a situation, the semiconductor device 10 of the present embodiment is configured so as to limit the current flowing through the output element by setting the gate voltage of the output element to a voltage lower than a turn-on voltage in the case where the overcurrent state of the output element is detected and the temperature of the output element has exceeded the set temperature, and then increasing the gate voltage as the temperature decreases below the set temperature, as described above.

With this configuration, when the output element has gone into the overcurrent state, an operation of limiting the current is performed depending on a result of detecting the temperature of the output element. The operation of limiting the current continues until the temperature decreases while the load is short-circuited. Consequently, it becomes possible to restrict the high-current operation in a high temperature state during the overcurrent state and thus to improve the reliability of the operation of the output element. Furthermore, it also becomes possible to avoid the occurrence of the electromigration phenomenon.

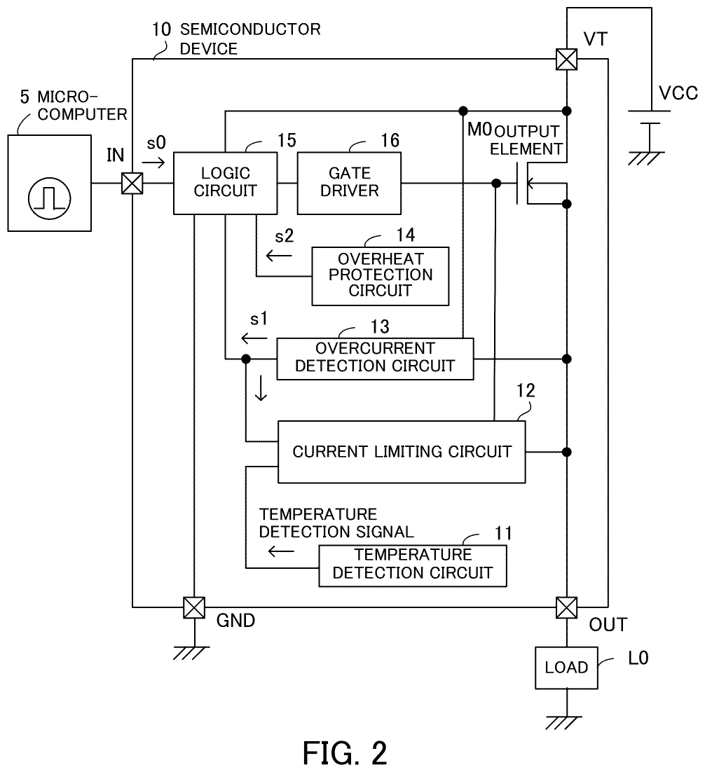

The following describes the configuration and operation of the semiconductor device 10 in detail. FIG. 2 illustrates an example of the configuration of the semiconductor device. For example, the semiconductor device 10 is applied to a high-side intelligent power switch (IPS), and includes an input terminal IN, an output terminal OUT, a power supply terminal VT, and a ground terminal GND.

The input terminal IN is connected to a microcomputer 5 (host controller) and receives a pulse-shaped control signal s0 output from the microcomputer 5. The output terminal OUT is connected to the load L0. Examples of the load L0 include an inductance load such as a solenoid valve, which is widely used in automobiles, and a resistive load such as a heater. The power supply terminal VT is connected to a power supply voltage VCC such as a battery, and the ground terminal GND is grounded.

In addition, the semiconductor device 10 includes the output element M0, the temperature detection circuit 11, the current limiting circuit 12, the overcurrent detection circuit 13, an overheat protection circuit 14, a logic circuit 15, and a gate driver 16. The logic circuit 15 receives the control signal s0 sent from the microcomputer 5 via the input terminal IN and generates a logic signal for turning on or off the output element M0.

For example, when the logic circuit 15 receives an H-level control signal s0 via the input terminal IN, the logic circuit 15 outputs a logic signal for turning on the output element M0. The gate driver 16 generates a voltage for turning on the output element M0 on the basis of the logic signal output from the logic circuit 15, and applies the voltage to the gate of the output element M0 to turn on the output element M0.

When the logic circuit 15 receives an L-level control signal s0 sent from the microcomputer 5 via the input terminal IN, on the other hand, the logic circuit 15 outputs a logic signal for turning off the output element M0. The gate driver 16 generates a signal whose level corresponds to turning off the output element M0, on the basis of the logic signal output from the logic circuit 15, and applies the signal to the gate of the output element M0 to turn off the output element M0.

The overcurrent detection circuit 13 detects the overcurrent state of the output element M0. When the overcurrent detection circuit 13 detects that a current abnormally higher than the rated current has flowed through the output element M0 during the ON state of the output element M0, the overcurrent detection circuit 13 sends an overcurrent detection signal s1 to the logic circuit 15.

In this connection, when the logic circuit 15 receives the overcurrent detection signal s1 sent from the overcurrent detection circuit 13, the logic circuit 15 outputs a logic signal for turning off the output element M0. The gate driver 16 then turns off the output element M0 on the basis of the logic signal output from the logic circuit 15. In this connection, the operation described in the present embodiment is entirely an operation that is performed before the output element M0 is turned off.

The overheat protection circuit 14 detects the overheat state of the output element M0. In this case, the potential generated by causing a constant current to flow through a temperature-detection diode, not illustrated, arranged in the vicinity of the output element M0 is applied as an overheat temperature detection voltage to the overheat protection circuit 14.

When the overheat protection circuit 14 detects the overheat state of the output element M0 on the basis of the overheat temperature detection voltage, the overheat protection circuit 14 outputs an overheat detection signal s2. In this connection, when the logic circuit 15 receives the overheat detection signal s2 sent from the overheat protection circuit 14, the logic circuit 15 outputs a logic signal for turning off the output element M0. The gate driver 16 then turns off the output element M0 on the basis of the logic signal output from the logic circuit 15.

The temperature detection circuit 11 detects the temperature state of the output element M0. Here, there are n temperature stages (n is a natural number), and the temperature detection circuit 11 outputs n temperature detection signals corresponding to the n temperature stages. In the case where the output element M0 is in the overcurrent state, the current limiting circuit 12 adjusts and limits the current flowing through the output element M0 on the basis of the temperature state (n temperature detection signals) detected by the temperature detection circuit 11.

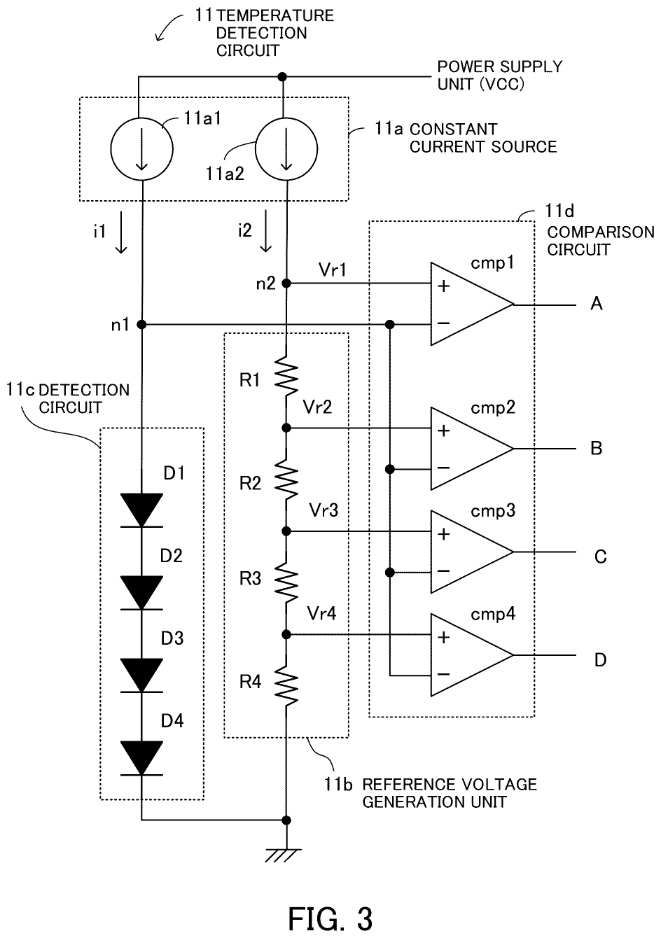

FIG. 3 illustrates an example of the configuration of a temperature detection circuit. The temperature detection circuit 11 includes a constant current source 11a (temperature-detection constant current source), a reference voltage generation unit 11b, a detection circuit 11c, and a comparison circuit 11d. The constant current source 11a includes a constant current element 11a1 (first constant current element) and a constant current element 11a2 (second constant current element). The reference voltage generation unit 11b includes resistors R1 to R4. The resistors R1 to R4 correspond to first to fourth resistors, respectively. The following describes an example of providing four resistors and four comparators, which will be described later. In this connection, the number of resistors and the number of comparators may desirably be set.

The detection circuit 11c includes temperature sensing diodes D1 to D4, each of which provides a temperature detection voltage that is based on a current from the constant current source 11a and that decreases with an increase in temperature. The comparison circuit 11d includes comparators cmp1 to cmp4. In this connection, the comparators cmp1 to cmp4 correspond to first to fourth comparators, respectively.

As to the connectivity of the component elements, the input terminal of the constant current element 11a1 is connected to the input terminal of the constant current element 11a2 and a power supply unit. The output terminal of the constant current element 11a1 is connected to the anode of the temperature sensing diode D1, the inverting input terminal (−) of the comparator cmp1, the inverting input terminal (−) of the comparator cmp2, the inverting input terminal (−) of the comparator cmp3, and the inverting input terminal (−) of the comparator cmp4.

The cathode of the temperature sensing diode D1 is connected to the anode of the temperature sensing diode D2, the cathode of the temperature sensing diode D2 is connected to the anode of the temperature sensing diode D3, and the cathode of the temperature sensing diode D3 is connected to the anode of the temperature sensing diode D4. The number of temperature sensing diodes D1 to D4 connected in series is not limited to four, but any number of temperature sensing diodes may be provided.

The output terminal of the constant current element 11a2 is connected to the non-inverting input terminal (+) of the comparator cmp1 and one end of the resistor R1. The other end of the resistor R1 is connected to one end of the resistor R2 and the non-inverting input terminal (+) of the comparator cmp2.

The other end of the resistor R2 is connected to one end of the resistor R3 and the non-inverting input terminal (+) of the comparator cmp3. The other end of the resistor R3 is connected to one end of the resistor R4 and the non-inverting input terminal (+) of the comparator cmp4. The other end of the resistor R4 is connected to the cathode of the temperature sensing diode D4 and is grounded.

Here, a current i1 that flows from the constant current element 11a1 toward the temperature sensing diodes D1 to D4 is a forward current for the temperature sensing diodes D1 to D4. Therefore, the voltage (temperature detection voltage) at the node n1 is the sum of the forward voltages (hereinafter, denoted by forward voltages Vf) of the temperature sensing diodes D1 to D4. For example, assuming that the forward voltage Vf of each temperature sensing diode D1 to D4 is 0.8 V, the temperature detection voltage at the node n1 is obtained as 3.2 (=0.8×4) V.

Note that the temperature sensing diodes D1 to D4 have temperature characteristics, and each forward voltage Vf depends on temperature. For example, when the temperature increases by 1° C., the forward voltage Vf decreases by 2 mV.

Therefore, for example, in the case where the temperature increases from 25° C. to 50° C., the forward voltage Vf of one temperature sensing diode decreases by 0.05 (=0.002×25) V.

Therefore, in the case where the forward voltages Vf are 0.8 V when the temperature is 25° C. and the temperature increases to 50° C., the decrease in the sum of the forward voltages Vf of the temperature sensing diodes D1 to D4 is 0.2 (=0.05×4) V, and the temperature detection voltage at the node n1 is obtained as 3.0 (=3.2−0.2) V.

As described above, the temperature detection voltage at the node n1 is obtained as 3.2 V when the temperature is 25° C., and is obtained as 3.0 V when the temperature is 50° C. That is, the temperature detection voltage depends on the temperature, i.e., decreases with an increase in the temperature.

Assuming now that a current i2 is output from the constant current element 11a2 (the currents i1 and i2 may be equal to or different from each other) and a voltage Vr1 is applied to the node n2, a reference voltage Vr1 is applied to the non-inverting input terminal (+) of the comparator cmp1.

In addition, a reference voltage Vr2 that is applied to the non-inverting input terminal (+) of the comparator cmp2 is obtained as Vr2=(R2+R3+R4)·Vr1/(R1+R2+R3+R4), based on the resistor voltage dividing principle.

Further, a reference voltage Vr3 that is applied to the non-inverting input terminal (+) of the comparator cmp3 is obtained as Vr3=(R3+R4)·Vr1/(R1+R2+R3+R4), based on the resistor voltage dividing principle.

Still further, a reference voltage Vr4 that is applied to the non-inverting input terminal (+) of the comparator cmp4 is obtained as Vr4=R4·Vr1/(R1+R2+R3+R4), based on the resistor voltage dividing principle. In this connection, the reference voltages Vr1 to Vr4 have a relationship of Vr4<Vr3<Vr2<Vr1.

Assume now that a total of four temperatures T are referenced for detection and let Tj1 to Tj4 denote the four temperatures (Tj1<Tj2<Tj3<Tj4), respectively. In addition, let Vt1 denote the temperature detection voltage at the node n1 in the case of the temperature Tj1, and Vt2 denote the temperature detection voltage at the node n1 in the case of the temperature Tj2.

Also, let Vt3 denote the temperature detection voltage at the node n1 in the case of the temperature Tj3, and Vt4 denote the temperature detection voltage at the node n1 in the case of the temperature Tj4. In this connection, the temperature detection voltages Vt1 to Vt4 have a relationship of Vt4<Vt3<Vt2<Vt1.

In the temperature detection circuit 11, in the case where the temperature T of the output element M0, which is a temperature detection target, during the operation thereof is in the range of T<Tj1, L-level temperature detection signals A, B, C, and D are output from the comparators cmp1, cmp2, cmp3, and cmp4, respectively.

Furthermore, in the case where the temperature T is in the range of Tj1≤T<Tj2, the temperature detection voltage Vt1 becomes lower than the reference voltage Vr1 but higher than the reference voltages Vr2, Vr3, and Vr4. Consequently, an H-level temperature detection signal A is output from the comparator cmp1, and L-level temperature detection signals B, C, and D are output from the comparators cmp2, cmp3, and cmp4, respectively.

In the case where the temperature increases to the range of Tj2≤T<Tj3, the temperature detection voltage Vt2 becomes lower than the reference voltages Vr1 and Vr2 but higher than the reference voltages Vr3 and Vr4. Consequently, H-level temperature detection signals A and B are output from the comparators cmp1 and cmp2, respectively, and L-level temperature detection signals C and D are output from the comparators cmp3 and cmp4, respectively.

In the case where the temperature further increases to the range of Tj3≤T<Tj4, the temperature detection voltage Vt3 becomes lower than the reference voltages Vr1, Vr2, and Vr3 but higher than the reference voltage Vr4. Consequently, H-level temperature detection signals A, B, and C are output from the comparators cmp1, cmp2 and cmp3, respectively, and an L-level temperature detection signal D is output from the comparator cmp4.

In the case where the temperature further increases to the range of Tj4≤T, the temperature detection voltage Vt4 becomes lower than the reference voltages Vr1, Vr2, Vr3, and Vr4. Consequently, H-level temperature detection signals A, B, C, and D are output from the comparators cmp1, cmp2, cmp3, and cmp4, respectively.

In this manner, in the above-described temperature detection circuit 11, as the temperature increases, H-level (predetermined-level) temperature detection signals are output in stages from the comparators cmp1 to cmp4. Consider now the outputs of the comparators cmp1 to cmp4 as digital logic outputs (with 1 indicating an H level and 0 indicating an L level), and let (A, B, C, D) represent the outputs of the comparators cmp1 to cmp4. In the case where the temperature T of the output element M0, which is a temperature detection target, is in the range of T<Tj1, the outputs are expressed as (A, B, C, D)=(0, 0, 0, 0).

In the case where the temperature T is in the range of Tj1≤T<Tj2, the outputs are expressed as (A, B, C, D)=(1, 0, 0, 0). In the case where the temperature T is in the range of Tj2<T<Tj3, the outputs are expressed as (A, B, C, D)=(1, 1, 0, 0). In addition, in the case where the temperature T is in the range of Tj3≤T<Tj4, the outputs are expressed as (A, B, C, D)=(1, 1, 1, 0). In the case where the temperature T is in the range of Tj4≤T, the outputs are expressed as (A, B, C, D)=(1, 1, 1, 1).

As described above, the temperature detection circuit 11 outputs n temperature detection signals for the n temperature stages (where n is a natural number). In the above example of n=4, four temperatures are referenced for the detection, and therefore four temperature detection signals A, B, C, and D are output.

Furthermore, the reference voltage generation unit 11b generates n reference voltages on the basis of a current flowing from the constant current source 11a in such a manner that the n reference voltages have voltage values in a descending order from the first reference voltage to a k-th reference voltage (1≤k≤n).

In the above example of n=4, the reference voltage generation unit 11b generates the first reference voltage Vr1, the second reference voltage Vr2, the third reference voltage Vr3, and the fourth reference voltage Vr4 (Vr4<Vr3<Vr2<Vr1).

Then, the comparison circuit 11d compares the k-th (1≤k≤n) reference voltage among the n reference voltages with the temperature detection voltage. If the k-th reference voltage is higher than the temperature detection voltage, the comparison circuit 1 11d outputs first up to k-th temperature detection signals.

In the above example of n=4, the comparison circuit 11d compares the first reference voltage Vr1 among the four reference voltages with the temperature detection voltage. If the first reference voltage is higher than the temperature detection voltage, the comparison circuit 11d outputs the first temperature detection signal A (H-level temperature detection signal A). In addition, the comparison circuit 11d compares the second reference voltage Vr2 among the four with the temperature detection voltage. If the second reference voltage Vr2 is higher than the temperature detection voltage, the comparison circuit 11d outputs the first up to second (i.e., the first and second) temperature detection signals A and B (H-level temperature detection signals A and B).

In addition, the comparison circuit 11d compares the third reference voltage Vr3 among the four with the temperature detection voltage. If the third reference voltage Vr3 is higher than the temperature detection voltage, the comparison circuit 11d outputs the first up to third (i.e., the first, second, and third) temperature detection signals A, B, and C (H-level temperature detection signals A, B, and C). In addition, the comparison circuit 11d compares the fourth reference voltage Vr4 among the four with the temperature detection voltage. If the fourth reference voltage Vr4 is higher than the temperature detection voltage, the comparison circuit 11d outputs the first up to fourth (i.e., the first, second, third, and fourth) temperature detection signals A, B, C, and D (H-level temperature detection signals A, B, C, and D).

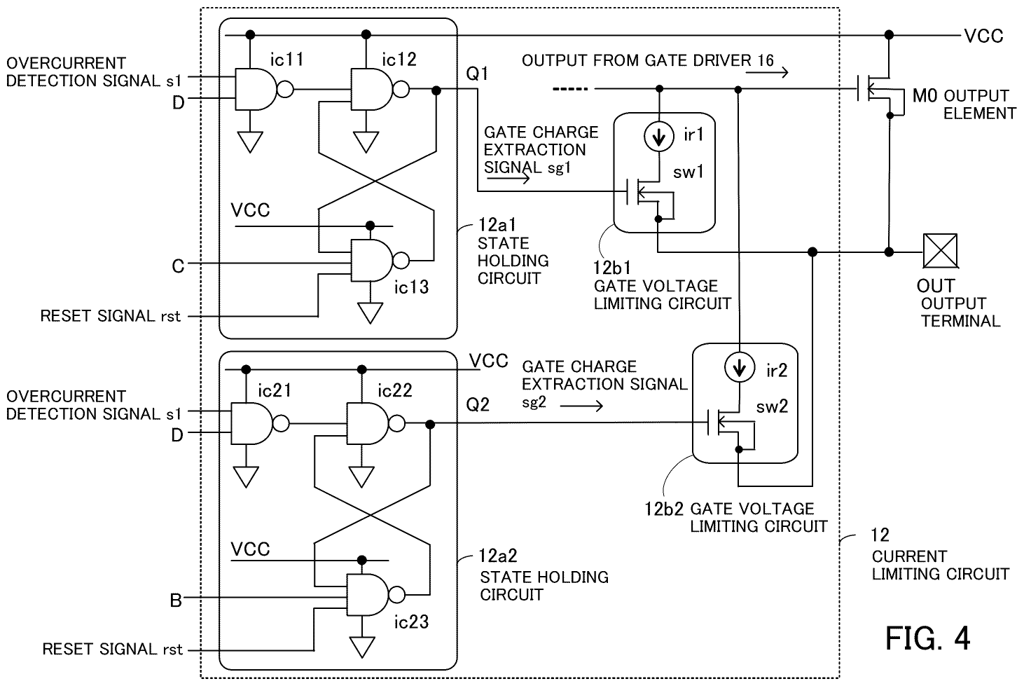

FIG. 4 illustrates an example of the configuration of a current limiting circuit. The current limiting circuit 12 includes state holding circuits 12a1 and 12a2 and gate voltage limiting circuits 12b1 and 12b2. The state holding circuit 12a1 (first state holding circuit) includes two-input, one-output negated logic AND circuits (hereinafter, NAND circuits) ic11 and ic12 and a three-input, one-output NAND circuit ic13. The state holding circuit 12a2 (second state holding circuit) includes two-input, one-output NAND circuits ic21 and ic22 and a three-input, one-output NAND circuit ic23.

The gate voltage limiting circuit 12b1 (first gate voltage limiting circuit) includes a constant current source ir1 and a switch sw1 (first switch), and the gate voltage limiting circuit 12b2 (second gate voltage limiting circuit) includes a constant current source ir2 and a switch sw2 (second switch). Each switch sw1 and sw2 is formed of an NMOS transistor.

As to the connectivity of the component elements, a first input terminal of the NAND circuit ic11 receives the overcurrent detection signal s1, and a second input terminal of the NAND circuit ic11 receives the temperature detection signal D. The output terminal of the NAND circuit ic11 is connected to a first input terminal of the NAND circuit ic12.

A second input terminal of the NAND circuit ic12 is connected to the output terminal of the NAND circuit ic13, and the output terminal of the NAND circuit ic12 is connected to the gate of the switch sw1 and a first input terminal of the NAND circuit ic13. An input terminal of the constant current source ir1 is connected to the output terminal of the gate driver 16, the gate of the output element M0, and the input terminal of the constant current source ir2. The output terminal of the constant current source ir1 is connected to the drain of the switch sw1.

The source of the switch sw1 is connected to the source of the switch sw2, the source of the output element M0, and the output terminal OUT. A second input terminal of the NAND circuit ic13 receives the temperature detection signal C, and a third input terminal of the NAND circuit ic13 receives a reset signal rst.

In addition, a first input terminal of the NAND circuit ic21 receives the overcurrent detection signal s1, and a second input terminal of the NAND circuit ic21 receives the temperature detection signal D. The output terminal of the NAND circuit ic21 is connected to a first input terminal of the NAND circuit ic22.

A second input terminal of the NAND circuit ic22 is connected to the output terminal of the NAND circuit ic23, and the output terminal of the NAND circuit ic22 is connected to the gate of the switch sw2 and a first input terminal of the NAND circuit ic23. The output terminal of the constant current source ir2 is connected to the drain of the switch sw2. A second input terminal of the NAND circuit ic23 receives the temperature detection signal B, and a third input terminal of the NAND circuit ic23 receives the reset signal rst.

When the output element M0 is in an overcurrent state, the current limiting circuit 12 configured as above receives temperature detection signals from the temperature detection circuit 11 and adjusts a gate voltage to be applied to the gate of the output element M0, so as to variably limit a current flowing through the output element M0. In this connection, the configuration of FIG. 4 is designed so that the current limitation is performed when the temperature T detected by the temperature detection circuit 11 is higher than or equal to the temperature Tj2 and that the temperature detection signals D, C, and B are used as inputs (note that the temperature detection signal A is not used).

The following describes the operation of the current limiting circuit 12 according to temperature changes. Here, the above-described ranges of Tj4≤T, Tj3≤T<Tj4, Tj2≤T<Tj3, and Tj1≤T<Tj2 are used for the temperature changes. The following describes how to perform current limitation in the case where the temperature T gradually decreases. The current limiting circuit 12 is so designed as to perform stronger current limitation as the operating temperature of the output element M0 in the overcurrent state becomes higher, and to reduce the current limitation as the operating temperature becomes lower.

Assume here that Tj4 corresponds to a set temperature, Tj3 corresponds to a first temperature, Tj2 corresponds to a second temperature, and Tj1 corresponds to a third temperature. In addition, assume that Tj4≤T corresponds to a first temperature range, Tj3≤T<Tj4 corresponds to a second temperature range, Tj2≤T<Tj3 corresponds to a third temperature range, and Tj1≤T<Tj2 corresponds to a fourth temperature range. Also, assume that an H-level temperature detection signal D corresponds to a first temperature detection signal, an H-level temperature detection signal C corresponds to a second temperature detection signal, an H-level temperature detection signal B corresponds to a third temperature detection signal, and an H-level temperature detection signal A corresponds to a fourth temperature detection signal.

Tj4≤T: Assume that the load L0 is short-circuited and an overcurrent state is detected in a high temperature state (a temperature state of Tj4≤T) around which overheat protection is activated. In this case, an H-level overcurrent detection signal s1 is output from the overcurrent detection circuit 13 and is input to the current limiting circuit 12. In addition, H-level temperature detection signals D, C, B, and A are output from the temperature detection circuit 11, and among these, the H-level temperature detection signals D, C, and B are input to the current limiting circuit 12.

At this time, in the state holding circuit 12a1, the output of the NAND circuit ic11 becomes L level, so that an H-level gate charge extraction signal sg1 (first gate charge extraction signal) is output from the output terminal Q1 of the state holding circuit 12a1 (i.e., from the output terminal of the NAND circuit ic12). In addition, in the state holding circuit 12a2, the output of the NAND circuit ic21 becomes L level, so that an H-level gate charge extraction signal sg2 (second gate charge extraction signal) is output from the output terminal Q2 of the state holding circuit 12a2 (i.e., from the output terminal of the NAND circuit ic22).

Since the H-level gate charge extraction signal sg1 is input to the gate of the switch sw1, the switch sw1 is turned on. Therefore, the gate of the output element M0 is conductively connected to the output terminal OUT via the gate voltage limiting circuit 12b1, so that gate charge is extracted from the gate of the output element M0 on the basis of the output current of the constant current source ir1.

In addition, since the H-level gate charge extraction signal sg2 is input to the gate of the switch sw2, the switch sw2 is turned on. Therefore, the gate of the output element M0 is conductively connected to the output terminal OUT via the gate voltage limiting circuit 12b2, so that gate charge is extracted from the gate of the output element M0 on the basis of the output current of the constant current source ir2.

As described above, in the case where the output element M0 is in the overcurrent state and the temperature state is in the range of Tj4≤T, the gate charge extraction signals sg1 and sg2 drive the two gate voltage limiting circuits 12b1 and 12b2, so that gate charge is extracted from the gate of the output element M0.

Letting Id1 denote a current flowing between the drain and the source of the output element M0 after the output element M0 prior to the extraction of gate charge is turned on, and Id2 denote a current flowing after the two gate voltage limiting circuits 12b1 and 12b2 are driven and gate charge is extracted from the gate of the output element M0, Id2<Id1 holds. That is to say, it is possible to limit the current flowing through the output element M0 in the high temperature state.

In this connection, the reset signal rst in the drawing is a power-on reset signal of the semiconductor device 10, and is, for example, generated within the semiconductor device 10 or sent from the microcomputer 5. The reset signal rst has L-level pulses when the semiconductor device 10 starts to operate, and is H level during the operation of the semiconductor device 10.

When the semiconductor device 10 starts to operate, the L-level pulse reset signal rst is input to the state holding circuits 12a1 and 12a2, so that the output terminals Q1 and Q2 of the state holding circuits 12a1 and 12a2 become L level, thereby resetting the state holding. Thus, the operation of extracting the gate charge from the gate of the output element M0 is stopped.

Tj3≤T<Tj4: Assume that the output element in the overcurrent state but the operating M0 is temperature T of the output element M0 has decreased to the range of Tj3≤T<Tj4. In this case, an H-level overcurrent detection signal s1 is output from the overcurrent detection circuit 13 and is input to the current limiting circuit 12. In addition, an L-level temperature detection signal D and H-level temperature detection signals C, B, and A are output from the temperature detection circuit 11, so that the L-level temperature detection signal D and H-level temperature detection signals C and B are input to the current limiting circuit 12.

At this time, in the state holding circuit 12a1, the output of the NAND circuit ic11 becomes H level, and the output of the NAND circuit ic13 becomes L level. Therefore, an H-level gate charge extraction signal sg1 is output from the output terminal Q1 of the state holding circuit 12a1 (i.e., from the output terminal of the NAND circuit ic12).

In the state holding circuit 12a2, on the other hand, the output of the NAND circuit ic21 becomes H level, and the output of the NAND circuit ic23 becomes L level. Therefore, an H-level gate charge extraction signal sg2 is output from the output terminal Q2 of the state holding circuit 12a2 (i.e., from the output terminal of the NAND circuit ic22). That is, in the case where the output element M0 is in the overcurrent state and the temperature state is in the range of Tj3≤T<Tj4, the two gate voltage limiting circuits 12b1 and 12b2 are driven, and the gate charge extraction signals sg1 and sg2 are output. Therefore, gate charge is extracted from the gate of the output element M0, thereby limiting the current flowing through the output element M0.

Tj2≤T<Tj3: Assume that the output element M0 is in the overcurrent state but the operating temperature T of the output element M0 has decreased to the range of Tj2≤T<Tj3. In this case, an H-level overcurrent detection signal s1 is output from the overcurrent detection circuit 13 and is then input to the current limiting circuit 12. In addition, L-level temperature detection signals D and C and H-level temperature detection signals B and A are output from the temperature detection circuit 11, so that the L-level temperature detection signals D and C and H-level temperature detection signal B are input to the current limiting circuit 12.

At this time, in the state holding circuit 12a1, the output of the NAND circuit ic11 becomes H level, and the output of the NAND circuit ic13 becomes H level. Therefore, an L-level gate charge extraction signal sg1 is output from the output terminal Q1 of the state holding circuit 12a1 (i.e., from the output terminal of the NAND circuit ic12).

In the state holding circuit 12a2, on the other hand, the output of the NAND circuit ic21 becomes H level, and the output of the NAND circuit ic23 becomes L level. Therefore, an H-level gate charge extraction signal sg2 is output from the output terminal Q2 of the state holding circuit 12a2 (i.e., from the output terminal of the NAND circuit ic22).

Since the L-level gate charge extraction signal sg1 is input to the gate of the switch sw1, the switch sw1 is turned off. On the other hand, since the H-level gate charge extraction signal sg2 is input to the gate of the switch sw2, the switch sw2 is turned on, so that gate charge is extracted from the gate of the output element M0.

Letting Id3 denote a current flowing after one gate voltage limiting circuit 12b2 is driven and gate charge is extracted from the gate of the output element M0, Id3<Id1 holds. That is to say, it is possible to limit the current flowing through the output element M0 in the high temperature state. In this connection, since only the gate voltage limiting circuit 12b2 causes the extraction of the gate charge, Id2<Id3 holds. That is, weak current limitation is performed, as compared with the cases where the temperature state is in the ranges of Tj4≤T and Tj3≤T<Tj4.

Tj1≤T<Tj2: Assume that the output element M0 is in the overcurrent state but the operating temperature T of the output element M0 has decreased to the range of Tj1≤T<Tj2. In this case, an H-level overcurrent detection signal s1 is output from the overcurrent detection circuit 13 and is then input to the current limiting circuit 12. In addition, L-level temperature detection signals D, C, and B and an H-level temperature detection signal A are output from the temperature detection circuit 11, so that the L-level temperature detection signals D, C, and B are input to the current limiting circuit 12.

In this case, in the state holding circuit 12a1, the output of the NAND circuit ic11 becomes H level, and the output of the NAND circuit ic13 becomes H level. Therefore, an L-level gate charge extraction signal sg1 is output from the output terminal Q1 of the state holding circuit 12a1 (i.e., from the output terminal of the NAND circuit ic12).

In the state holding circuit 12a2, on the other hand, the output of the NAND circuit ic21 becomes H level, and the output of the NAND circuit ic23 becomes H level. Therefore, an L-level gate charge extraction signal sg2 is output from the output terminal Q2 of the state holding circuit 12a2 (i.e., from the output terminal of the NAND circuit ic22).

Since the L-level gate charge extraction signal sg1 is input to the gate of the switch sw1, the switch sw1 is turned off. Since the L-level gate charge extraction signal sg2 is input to the gate of the switch sw2, the switch sw2 is turned off. Therefore, gate charge is not extracted from the gate of the output element M0. That is, in the configuration of FIG. 4, in the case where the output element M0 is in the overcurrent state but the temperature state is in the range of Tj1≤T<Tj2, no current limitation is performed.

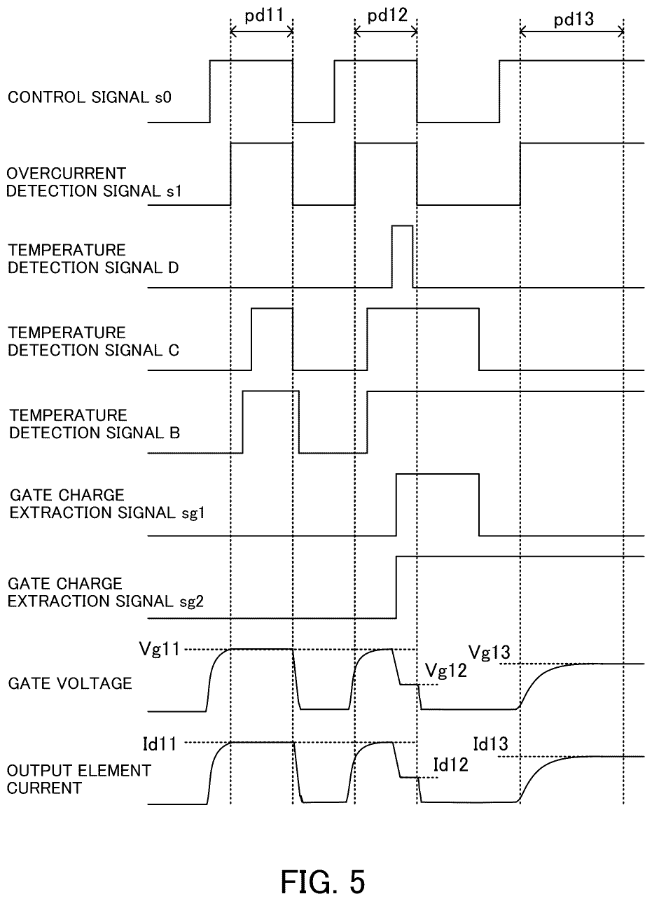

FIG. 5 is a time chart representing an example of the operation of the current limiting circuit. In this connection, the illustration of the temperature detection signal A is omitted.

Period pd11: An H-level control signal s0 is input to the input terminal IN, so that the output element M0 is turned on. In addition, the load becomes short-circuited and this causes an overcurrent state. Therefore, an H-level overcurrent detection signal s1 is output from the overcurrent detection circuit 13.

Although an L-level temperature detection signal D and H-level temperature detection signals C and B are output because of the temperature T of the output element M0, the control signal s0 becomes L level before the temperature T reaches the set temperature, which turns off the output element M0. Thus, the current limiting operation is not performed.

Since gate charge is not extracted from the gate of the output element M0, the gate voltage of the output element M0 is at the voltage level Vg11 of a turn-on instruction signal output from the gate driver 16, and a current (output element current) Id11 flows between the drain and the source of the output element M0.

Period pd12: An H-level control signal s0 is input to the input terminal IN after an L-level control signal s0 is input to the input terminal IN to thereby turn off the output element M0, so that the output element M0 is turned on. Since the load is repeatedly short-circuited, the overcurrent state is occurring. Therefore, an H-level overcurrent detection signal s1 is output from the overcurrent detection circuit 13.

Assume that the temperature T of the output element M0 has increased to the range of, for example, Tj4≤T, higher than the case of the period pd11. In this case, H-level temperature detection signals D, C, and B are output from the temperature detection circuit 11. Therefore, as described above, an H-level gate charge extraction signal sg1 is output from the state holding circuit 12a1 and an H-level gate charge extraction signal sg2 is output from the state holding circuit 12a2.

Since gate charge is extracted through two routes created by the gate charge extraction signals sg1 and sg2, the gate voltage of the output element M0 transitions to a voltage level Vg12 lower than the voltage level Vg11 (Vg12<Vg11), and a current Id12 lower than the current Id11 flows between the drain and the source of the output element M0 (Id12<Id11).

Period pd13: An H-level control signal s0 is input to the input terminal IN after an L-level control signal s0 is input to the input terminal IN to thereby turn off the output element M0, so that the output element M0 is turned on. Since the load is repeatedly short-circuited, the overcurrent state is occurring. Therefore, an H-level overcurrent detection signal s1 is output from the overcurrent detection circuit 13.

Assume now that the current limitation based on the gate charge extraction control has been performed during the period pd12 and that the temperature T of the output element M0 has decreased to the range of, for example, Tj2≤T<Tj3 during the OFF period. In this case, L-level temperature detection signals D and C and an H-level temperature detection signal B are output from the temperature detection circuit 11. Therefore, as described above, an L-level gate charge extraction signal sg1 is output from the state holding circuit 12a1, and an H-level gate charge extraction signal sg2 is output from the state holding circuit 12a2.

Since gate charge is extracted through one route created by the gate charge extraction signal sg2, the gate voltage of the output element M0 transitions to a voltage level Vg13 lower than the voltage level Vg11 but higher than the voltage level Vg12 (Vg12<Vg13<Vg11). Therefore, a current Id13 that is lower than the current Id11 but higher than the current Id12 flows between the drain and the source of the output element M0 (Id12<Id13<Id11).

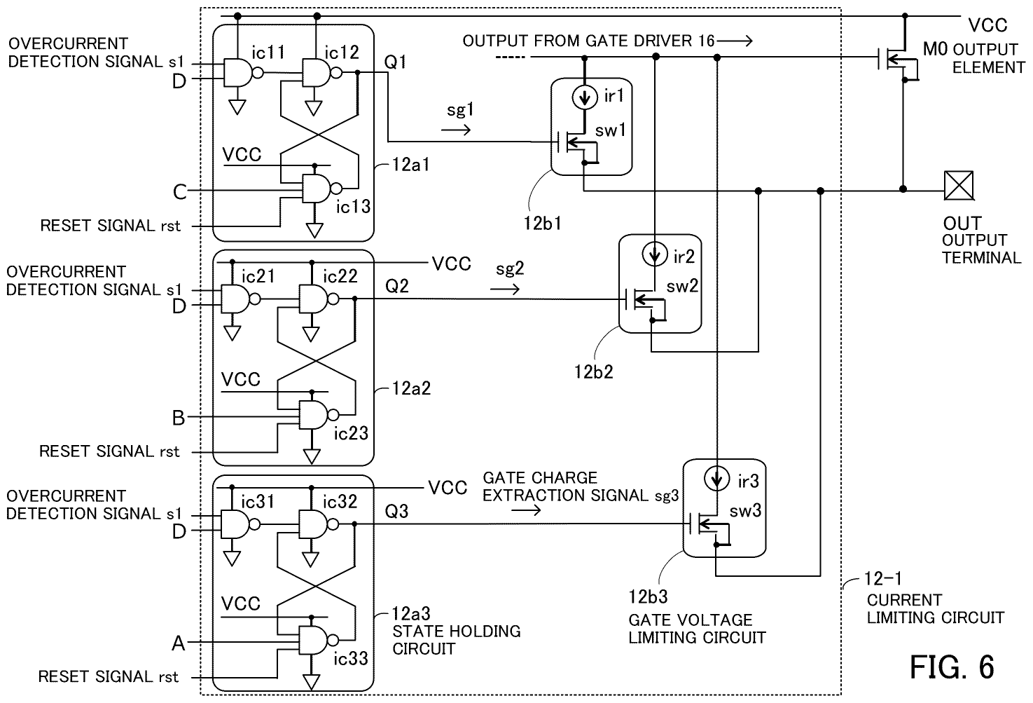

FIG. 6 illustrates an example of the configuration of a current limiting circuit. The current limiting circuit 12-1 illustrated in FIG. 6 has a circuit configuration that enables up to the detection of a temperature state using the temperature detection signal A. The current limiting circuit 12-1 includes state holding circuits 12a1, 12a2, and 12a3 and gate voltage limiting circuits 12b1, 12b2, and 12b3. The state holding circuit 12a3 includes two-input, one-output NAND circuits ic31 and ic32 and a three-input, one-output NAND circuit ic33. The gate voltage limiting circuit 12b3 includes a constant current source ir3 and a switch sw3. In this connection, the switch sw3 is formed of an NMOS transistor.

A first input terminal of the NAND circuit ic31 receives the overcurrent detection signal s1, and a second input terminal of the NAND circuit ic31 receives the temperature detection signal D. The output terminal of the NAND circuit ic31 is connected to a first input terminal of the NAND circuit ic32.

A second input terminal of the NAND circuit ic32 is connected to the output terminal of the NAND circuit ic33, and the output terminal of the NAND circuit ic32 is connected to the gate of the switch sw3 and a first input terminal of the NAND circuit ic33. The input terminal of the constant current source ir3 is connected to the output terminal of the gate driver 16, the gate of the output element M0, and the input terminals of the constant current sources ir1 and ir2, and the output terminal of the constant current source ir3 is connected to the drain of the switch sw3.

The source of the switch sw3 is connected to the source of the output element M0, the sources of the switches sw1 and sw2, and the output terminal OUT. A second input terminal of the NAND circuit ic33 receives the temperature detection signal A, and a third input terminal of the NAND circuit ic33 receives the reset signal rst. In this connection, the other configuration is the same as that of FIG. 4.

In the current limiting circuit 12-1 configured as above, in the case where the temperature T of the output element M0 in the overcurrent state is in the range of Tj4≤T, the temperature detection signals D, C, B, and A become H level, and the gate charge extraction signals sg1 and sg2 and gate charge extraction signal sg3 become H level. Therefore, the switches sw1, sw2, and sw3 are turned on, so that gate charge is extracted from the gate of the output element M0 through the three routes.

In addition, in the case where the temperature T of the output element M0 in the overcurrent state is in the range of Tj3≤T<Tj4, the temperature detection signal D becomes L level, the temperature detection signals C, B, and A become H level, and the gate charge extraction signals sg1, sg2, and sg3 become H level. Therefore, the switches sw1, sw2, and sw3 are turned on, so that gate charge is extracted from the gate of the output element M0 through the three routes.

In addition, in the case where the temperature T of the output element M0 in the overcurrent state is in the range of Tj2≤T<Tj3, the temperature detection signals D and C become L level, the temperature detection signals B and A become H level, the gate charge extraction signal sg1 becomes L level, and the gate charge extraction signals sg2 and sg3 become H level. Therefore, the switch sw1 is turned off and the switches sw2 and sw3 are turned on, so that gate charge is extracted from the gate of the output element M0 through the two routes.

Furthermore, in the case where the temperature T of the output element M0 in the overcurrent state is in the range of Tj1≤T<Tj2, the temperature detection signals D, C, and B become L level, the temperature detection signal A becomes H level, the gate charge extraction signals sg1 and sg2 become L level, and the gate charge extraction signal sg3 becomes H level. Therefore, the switches sw1 and sw2 are turned off, and the switch sw3 is turned on, so that gate charge is extracted from the gate of the output element M0 through the one route.

Then, in the case where the temperature T of the output element M0 in the overcurrent state is in the range of T<Tj1, the temperature detection signals D, C, B, and A become L level, the gate charge extraction signals sg1, sg2, and sg3 become L level. Therefore, the switches sw1, sw2, and sw3 are turned off, so that gate charge is not extracted from the gate of the output element M0.

In this connection, the above example provides four temperature detection signals, three state holding circuits, and three gate voltage limiting circuits. However, the number of temperature detection signals, the number of state holding circuits, and the number of gate voltage limiting circuits are not limited thereto.

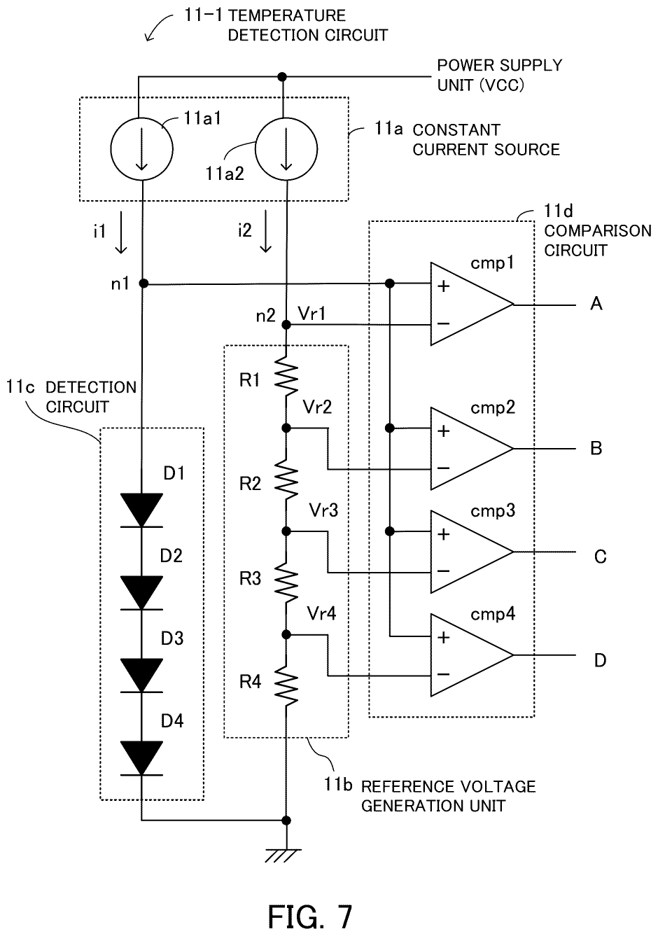

In addition, as a second example, the input to the inverting input terminal of each comparator in the comparison circuit 11d of FIG. 3 and the input to the non-inverting input terminal thereof may be reversed in such a manner that the output of the node n1 is input to the non-inverting input terminals of the comparators and the reference voltages Vr1 to Vr4 generated by the reference voltage generation unit are respectively applied to the inverting input terminals thereof. The configuration of a temperature detection circuit 11-1 in this example is illustrated in FIG. 7.

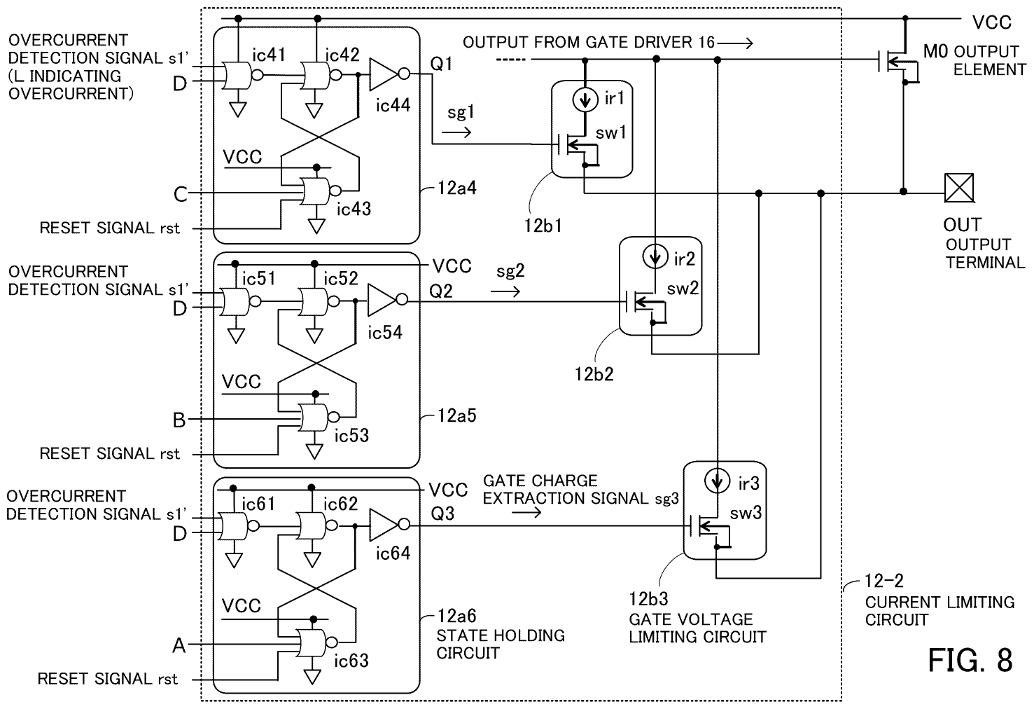

In addition, the configuration of a current limiting circuit 12-2 in the second example is illustrated in FIG. 8. All the NAND circuits ic11 to ic13, ic21 to ic23, and ic31 to ic33 are replaced with negated logic OR circuits (NOR circuits) ic41 to ic43, ic51 to ic53, and ic61 to ic63, the overcurrent detection signal s1 is replaced with an overcurrent detection signal s1′ whose L level indicates the detection of an overcurrent, and NOT circuits ic44, ic54, and ic64 are connected to the outputs of the NOR circuits ic42, ic52, and ic62, respectively. The other configuration is the same as illustrated in FIGS. 3 and 4.

FIG. 7 illustrates an example of the configuration of the temperature detection circuit. The temperature detection circuit 11-1 includes a constant current source 11a (temperature-detection constant current source), a reference voltage generation unit 11b, a detection circuit 11c, and a comparison circuit 11d. The constant current source 11a includes a constant current element 11a1 (first constant current element) and a constant current element 11a2 (second constant current element), and the reference voltage generation unit 11b includes resistors R1 to R4.

The detection circuit 11c includes temperature sensing diodes D1 to D4, each of which provides a temperature detection voltage that is based on a current from the constant current source 11a and that decreases with an increase in temperature. The comparison circuit 11d includes comparators cmp1 to cmp4. In this connection, the comparators cmp1 to cmp4 correspond to first to fourth comparators, respectively.

The different features from the configuration of FIG. 3 are that the non-inverting input terminals (+) of the comparators cmp1 to cmp4 are connected to the node n1 between the output terminal of the constant current element 11a1 and the anode of the temperature sensing diode D1.

In addition, the inverting input terminal (−) of the comparator cmp1 is connected to the node n2 between the output terminal of the constant current element 11a2 and one end of the resistor R1, and the inverting input terminal (−) of the comparator cmp2 is connected between the other end of the resistor R1 and one end of the resistor R2.

Furthermore, the inverting input terminal (−) of the comparator cmp3 is connected between the other end of the resistor R2 and one end of the resistor R3, and the inverting input terminal (−) of the comparator cmp4 is connected between the other end of the resistor R3 and one end of the resistor R4. The other configuration is the same as illustrated in FIG. 3.

The temperature detection circuit 11 illustrated in FIG. 3 outputs a predetermined-level (H-level) temperature detection signal in the case where a reference voltage is higher than a temperature detection voltage. By contrast, the temperature detection circuit 11-1 outputs a predetermined-level (L-level) temperature detection signal in the case where a reference voltage is higher than a temperature detection voltage.

FIG. 8 illustrates an example of the configuration of a current limiting circuit. The current circuit 12-2 includes such limiting a circuit configuration as to receive an overcurrent detection signal s1′, which becomes L level when an overcurrent is detected, and temperature detection signals A, B, C, and D output from the temperature detection circuit 11-1 illustrated in FIG. 7 and perform current limitation. The limiting circuit 12-2 includes state holding current circuits 12a4, 12a5, and 12a6 and gate voltage limiting circuits 12b1, 12b2, and 12b3.

The state holding circuit 12a4 includes two-input, one-output negated logic OR circuits (hereinafter, referred to as NOR circuits) ic41 and ic42, a three-input, one-output NOR circuit ic43, and an inverter circuit ic44. The state holding circuit 12a5 includes two-input, one-output NOR circuits ic51 and ic52, a three-input, one-output NOR circuit ic53, and an inverter circuit ic54. The state holding circuit 12a6 includes two-input, one-output NOR circuits ic61 and ic62, a three-input, one-output NOR circuit ic63, and an inverter circuit ic64. The gate voltage limiting circuits 12b1, 12b2, and 12b3 have the same configuration as those illustrated in FIG. 6.

The connectivity of component elements different from that illustrated in FIG. 6 will now be described. A first input terminal of the NOR circuit ic41 receives the overcurrent detection signal s1′ (whose L level indicates the detection of an overcurrent), and a second input terminal of the NOR circuit ic41 receives the temperature detection signal D. The output terminal of the NOR circuit ic41 is connected to a first input terminal of the NOR circuit ic42.

A second input terminal of the NOR circuit ic42 is connected to the output terminal of the NOR circuit ic43, and the output terminal of the NOR circuit ic42 is connected to the input terminal of the inverter circuit ic44 and a first input terminal of the NOR circuit ic43. The output terminal of the inverter circuit ic44 is connected to the gate of the switch sw1. A second input terminal of the NOR circuit ic43 receives the temperature detection signal C, and a third input terminal of the NOR circuit ic43 receives a reset signal rst (this signal is inverted compared to that illustrated in FIGS. 4 and 6).

In addition, a first input terminal of the NOR circuit ic51 receives the overcurrent detection signal s1′ (whose L level indicates the detection of an overcurrent), and a second input terminal of the NOR circuit ic51 receives the temperature detection signal D. The output terminal of the NOR circuit ic51 is connected to a first input terminal of the NOR circuit ic52.

A second input terminal of the NOR circuit ic52 is connected to the output terminal of the NOR circuit ic53, and the output terminal of the NOR circuit ic52 is connected to the input terminal of the inverter circuit ic54 and a first input terminal of the NOR circuit ic53. The output terminal of the inverter circuit ic54 is connected to the gate of the switch sw2. A second input terminal of the NOR circuit ic53 receives the temperature detection signal B, and a third input terminal of the NOR circuit ic53 receives the reset signal rst (this signal is inverted compared to that illustrated in FIGS. 4 and 6).

Furthermore, a first input terminal of the NOR circuit ic61 receives the overcurrent detection signal s1′ (whose L level indicates the detection of an overcurrent), and a second input terminal of the NOR circuit ic61 receives the temperature detection signal D. The output terminal of the NOR circuit ic61 is connected to a first input terminal of the NOR circuit ic62.

A second input terminal of the NOR circuit ic62 is connected to the output terminal of the NOR circuit ic63, and the output terminal of the NOR circuit ic62 is connected to the input terminal of the inverter circuit ic64 and a first input terminal of the NOR circuit ic63. The output terminal of the inverter circuit ic64 is connected to the gate of the switch sw3. A second input terminal of the NOR circuit ic63 receives the temperature detection signal A, and a third input terminal of the NOR circuit ic63 receives the reset signal rst (this signal is inverted compared to that illustrated in FIGS. 4 and 6).

The above-described current limiting circuit 12-2 receives an inverted input signal. Therefore, by modifying the internal configuration of each state holding circuit such as to replace the NAND circuits with the NOR circuits and insert an inverter circuit as an output end, the current limiting circuit 12-2 is able to achieve the same functions as illustrated in FIG. 6.

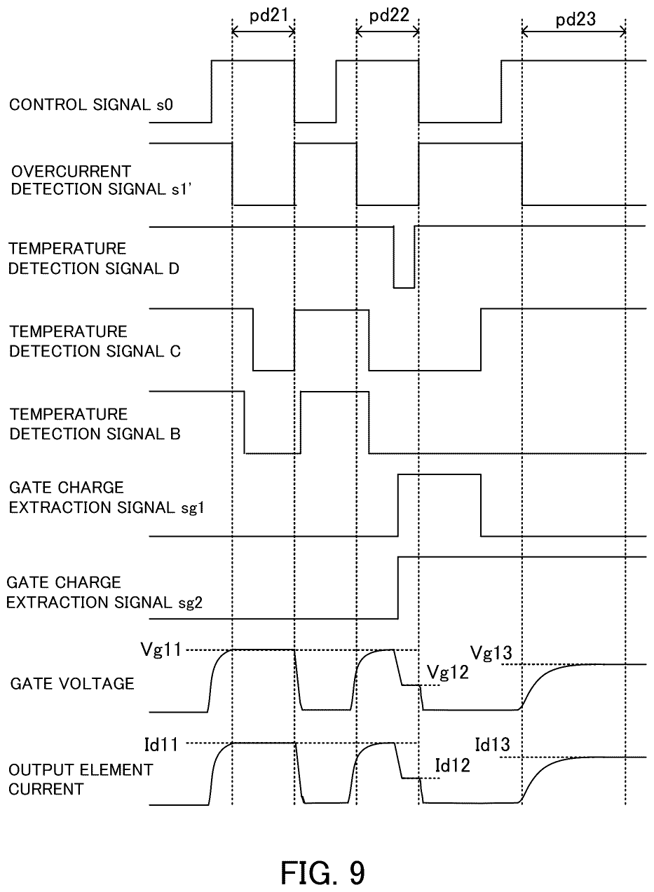

FIG. 9 is a time chart representing an example of the operation of the current limiting circuit. This time chart represents an operation example using temperature detection signals D, C, and B in the current limiting circuit 12-2 illustrated in FIG. 8.

Period pd21: An H-level control signal s0 is input to the input terminal IN, so that the output element M0 is turned on. In addition, the load becomes short-circuited and this causes an overcurrent state. Therefore, an L-level overcurrent detection signal s1′ is output from the overcurrent detection circuit 13.

Furthermore, an H-level temperature detection signal D and L-level temperature detection signals C and B are output because of the temperature T of the output element M0. However, since the control signal s0 becomes L level before the temperature T reaches the set temperature, the output element M0 is turned off. That is, the current limiting operation is not performed.

Since gate charge is not extracted, the gate voltage of the output element M0 is at the voltage level Vg11 of the turn-on instruction signal output from the gate driver 16, and a current (output element current) Id11 flows between the drain and the source of the output element M0.

Period pd22: An H-level control signal s0 is input to the input terminal IN after an L-level control signal s0 is input to the input terminal IN to thereby turn off the output element M0, so that the output element M0 is turned on. Since the load is repeatedly short-circuited, the overcurrent state is occurring. Therefore, an L-level overcurrent detection signal s1′ is output from the overcurrent detection circuit 13.

Assume now that the temperature T of the output element M0 increases to the range of, for example, Tj4≤T, higher than the case of the period pd21. In this case, L-level temperature detection signals D, C, and B are output from the temperature detection circuit 11-1. Therefore, an H-level gate charge extraction signal sg1 is output from the state holding circuit 12a4, and an H-level gate charge extraction signal sg2 is output from the state holding circuit 12a5.

Since gate charge is extracted through two routes created by the gate charge extraction signals sg1 and sg2, the gate voltage of the output element M0 transitions to a voltage level Vg12 lower than the voltage level Vg11 (Vg12<Vg11). In addition, a current Id12 lower than the current Id11 flows between the drain and the source of the output element M0 (Id12<Id11).

Period pd23: An H-level control signal s0 is input to the input terminal IN after an L-level control signal s0 is input to the input terminal IN to thereby turn off the output element M0, so that the output element M0 is turned on. Since the load is repeatedly short-circuited, the overcurrent state is occurring. Therefore, an L-level overcurrent detection signal s1′ is output from the overcurrent detection circuit 13.

Assume now that the current limitation based on the gate charge extraction control has been performed during the period pd22 and that the temperature T of the output element M0 has decreased to the range of, for example, Tj2≤T<Tj3 during the OFF period. In this case, H-level temperature detection signals D and C and an L-level temperature detection signal B are output from the temperature detection circuit 11-1. Therefore, an L-level gate charge extraction signal sg1 is output from the state holding circuit 12a4, and an H-level gate charge extraction signal sg2 is output from the state holding circuit 12a5.

Since gate charge is extracted through one route created by the gate charge extraction signal sg2, the gate voltage of the output element M0 transitions to a voltage level Vg13 lower than the voltage level Vg11 but higher than the voltage level Vg12 (Vg12<Vg13<Vg11). Therefore, a current Id13 that is lower than the current Id11 but higher than the current Id12 flows between the drain and the source of the output element M0 (Id12<Id13<Id11).

As described above, the technique of the present embodiment limits the current flowing through the output element depending on a temperature detection result obtained by the temperature detection circuit in the case where the output element has gone into an overcurrent state. That is, the control to limit the current continues until the operating temperature of the output element decreases to a certain temperature value while the load is short-circuited. Consequently, it becomes possible to restrict the high-current operation of the output element in a high temperature state and thus to improve the reliability of the operation of the output element. Furthermore, the above-described suppression of temperature increase and current limitation make it possible to avoid the occurrence of an electromigration that may cause conductor deformation and circuit failure.

Heretofore, the embodiment has been described. Each component in the embodiment may be replaced with another component having an equivalent function. In addition, other desired configurations and steps may be added. Furthermore, two or more desired configurations (features) in the embodiment described above may be combined.

According to one aspect, it is possible to restrict the high-current operation of an output element in a high temperature state during an overcurrent state and thus to improve the reliability of the operation of the output element.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an output terminal connected to a load, and a power supply terminal connected to a power supply;
an output element connected to the output terminal and to the power supply terminal, the output element being turned on by application of a predetermined turn-on voltage to a gate of the output element in a normal state;
an overcurrent detection circuit configured to detect an overcurrent state of the output element;
a temperature detection circuit configured to detect, as a detected temperature, a temperature of the output element during an operation of the output element using a reference temperature; and
a current limiting circuit configured to limit a current flowing through the output element by
setting a gate voltage of the output element to a set voltage lower than the predetermined turn-on voltage, in response to both detecting the overcurrent state and detecting that the detected temperature is equal to or higher than the set temperature, and increasing the set voltage in stages toward the predetermined turn-on voltage as the detected temperature decreases.

2. The semiconductor device according to claim 1, wherein
the reference temperature includes a total of (N-1) reference temperatures, which are first to (N-1)-th reference temperatures, different from one another, N being a natural number of 3 or higher, the set temperature being higher than the first reference temperature, the (n-2)-th reference temperature being higher than an (n-1)-th reference temperature, n being any natural number between 3 and N, inclusive,
the temperature detection circuit outputs a total of N temperature detection signals, the N temperature detection signals indicating that the detected temperature is in one of a total of N temperature ranges that do not overlap one another, the N temperature ranges being respectively using set respective ones of the set temperature and the (N-1) reference temperatures, and
the current limiting circuit limits the current flowing through the output element, based on the one of the N temperature ranges indicated by the N temperature detection signals.

3. The semiconductor device according to claim 2, wherein the current limiting circuit,
upon receiving the N temperature detection signals indicating that the detected temperature is equal to or higher than the set temperature,
generates a total of P gate charge extraction signals so as to extract gate charge from the gate of the output element according to the P gate charge extraction signals, P being a natural number less than N, and
upon receiving the N temperature detection signals indicating that the detected temperature is lower than one of the (N-1) reference temperatures, after the temperature detection circuit has detected that the detected temperature is equal to or higher than the set temperature,
generates a total of Q gate charge extraction signals so as to extract the gate charge from the gate according to the Q gate charge extraction signals, Q being a natural number less than P.

4. The semiconductor device according to claim 3, wherein the current limiting circuit,
upon receiving the N temperature detection signals indicating that the detected temperature is in a first temperature range defined by the detected temperature being no lower than the set temperature, or that the detected temperature is in a second temperature range defined by the detected temperature being no lower than the first reference temperature and lower than the set temperature, after the temperature detection circuit has detected that the detected temperature is in the first temperature range,
generates the first to (N-1)-th gate charge extraction signals so as to extract the gate charge from the gate by the first to (N-1)-th gate charge extraction signals, and
upon receiving the N temperature detection signals indicating that the detected temperature is in an (r+1)-th temperature range defined by the detected temperature being no lower than the r-th reference temperature and lower than the (r-1)-th reference temperature, after the temperature detection circuit has detected that the detected temperature is no lower than the set temperature,
generates the r-th to (N-1)-th gate charge extraction signals so as to extract the gate charge from the gate by the r-th to (N-1)-th gate charge extraction signals, r being any natural number between 2 and N-1, inclusive.

5. The semiconductor device according to claim 4, wherein
the temperature detection circuit outputs the N temperature detection signals, which are first to N-th temperature detection signals, each having a first level or a second level,
in a case where the detected temperature is in a k-th temperature range, k being any natural number between 1 and N, inclusive, the temperature detection circuit outputs the N temperature detection signals in which the k-th to N-th temperature detection signals having the first level,
the current limiting circuit includes
first to (N-1)-th holding state circuits configured to output the first to (N-1)-th gate charge extraction signals, respectively, and
first to (N-1)-th gate voltage limiting circuits configured to receive the first to (N-1)-th gate charge extraction signals, respectively, to control the set gate voltage of the gate of the output element, and
in response to the first to (N-1)-th state holding circuits receiving an overcurrent detection signal that is output from the overcurrent detection circuit upon the overcurrent detection circuit detecting the overcurrent state, and the first to k-th state holding circuits respectively first to k-th temperature detection signals having the first level,
the k-th state holding circuit outputs a k-th gate charge extraction signal until the k-th state holding circuit no longer receives the k-th temperature detection signal having the first level, and
a k-th gate voltage limiting circuit extracts the gate charge by conductively connecting the gate of the output element to the output terminal by the k-th gate charge extraction signal.

6. The semiconductor device according to claim 4, wherein
the temperature detection circuit outputs the N temperature detection signals, which are first to N-th temperature detection signals, each having a first level or a second level,
in a case where the detected temperature is in a k-th temperature range, k being any natural number between 1 and N, inclusive, the temperature detection circuit outputs the N temperature detection signals in which the first to (k-1)-th temperature detection signals having the first level,
the (N-1) extraction circuits of the current limiting circuit include
first to (N-1)-th state holding circuits configured to output the first to (N-1)-th gate charge extraction signals, respectively, and
first to (N-1)-th gate voltage limiting circuits configured to receive the first to (N-1)-th gate charge extraction signals, respectively, to control the set gate voltage of the gate of the output element, and
in response to the first to (N-1)-th state holding circuits receiving an overcurrent detection signal that is output from the overcurrent detection circuit upon the overcurrent detection circuit detecting the overcurrent state, and the first to k-th state holding circuits respectively receiving first to k-th temperature detection signals having the first level,
the k-th state holding circuit outputs a k-th gate charge extraction signal until the k-th state holding circuit receives the k-th temperature detection signal having the first level, after the first state holding circuit no longer receives the first temperature detection signal having the first level, and
a k-th gate voltage limiting circuit extracts the gate charge by conductively connecting the gate of the output element to the output terminal by the k-th gate charge extraction signal.

7. The semiconductor device according to claim 2, wherein the temperature detection circuit includes
a temperature-detection constant current source configured to output a first current and a second current,
a detection circuit including a temperature sensing diode through which the first current flows, and being configured to provide a temperature detection voltage that decreases with an increase in the detected temperature,
a reference voltage generation circuit configured to provide a total of N reference voltages different from one another, based on the second current, respectively corresponding to respective ones of the set temperature and the (N-1) reference temperatures, and
a comparison circuit configured to compare each of the N reference voltages with the temperature detection voltage and to output the N temperature detection signals, each having a first level or a second level, an n-th temperature detection signal among the N temperature detection signals having the first level in case where the n-th reference voltage is higher than the temperature detection voltage.

8. The semiconductor device according to claim 7, wherein
the N reference voltages are first to N-th reference voltages that have different values in a descending order from the first to N-th reference voltages, and
the comparison circuit outputs the N temperature detection signals in which the first to k-th temperature detection signals have the first level, upon determining that the k-th reference voltage is higher than the temperature detection voltage, k being any natural number between 1 and N, inclusive.

9. The semiconductor device according to claim 7, wherein
the temperature-detection constant current source includes a first constant current element to output the first current and a second constant current element to output the second current,
the reference voltage generation circuit includes a total of N resistors, which are first to n-th resistors, connected in series sequentially from a high potential side to a low potential side of the reference voltage generation circuit,
the comparison circuit includes a total of N comparators, which are first to n-th comparators,
the first constant current element includes an input terminal connected to an input terminal of the second constant current element and the power supply, and an output terminal connected to an anode of the temperature sensing diode and an inverting input terminal of each of the N comparators, a cathode of the temperature sensing diode being grounded,
the second constant current element includes an output terminal connected to a non-inverting input terminal of the first comparator and one end of the first resistor,
the first comparator outputs a first temperature detection signal from an output terminal thereof,
a k-th comparator includes a non-inverting input terminal connected directly to a high-potential end of a k-th resistor, k being any natural number between 1 and n, inclusive,
the k-th comparator outputs a k-th temperature detection signal from an output terminal thereof, and
the n-th resistor includes a low-potential end that is grounded.

10. The semiconductor device according to claim 2, wherein the temperature detection circuit includes
a temperature-detection constant current source configured to output a first current and a second current,
a detection circuit including a temperature sensing diode through which the first current flows, and being configured to provide a temperature detection voltage that decreases with an increase in the detected temperature,
a reference voltage generation circuit configured to provide a total of N reference voltages different from one another, based on the second current, respectively corresponding to respective ones of the set temperature and the (N-1) reference temperatures, and
a comparison circuit configured to compare each of the N reference voltages with the temperature detection voltage and to output the N temperature detection signals, each having a first level or a second level, an n-th temperature detection signal among the N temperature detection signals having the second level in case where the n-th reference voltage is higher than the temperature detection voltage.

11. The semiconductor device according to claim 10, wherein
the N reference voltages are a first reference voltage to an n-th reference voltage that have voltage values in a descending order from the first reference voltage to the N-th reference voltage, and
the comparison circuit outputs first to k-th temperature detection signals having the second level, upon determining that the k-th reference voltage is higher than the temperature detection voltage, k being any natural number between 1 and n, inclusive.

12. The semiconductor device according to claim 10, wherein
the temperature-detection constant current source includes a first constant current element to output the first current and a second constant current element to output the second current,
the reference voltage generation circuit includes a total of N resistors, which are first to n-th resistors, connected in series sequentially from a high potential side to a low potential side of the reference voltage generation circuit,
the comparison circuit includes a total of N comparators, which are first to n-th comparators,
the first constant current element includes an input terminal connected to an input terminal of the second constant current element and the power supply, and an output terminal connected to an anode of the temperature sensing diode and a non-inverting input terminal of each of the N comparators, a cathode of the temperature sensing diode being grounded,
the second constant current element includes an output terminal connected to an inverting input terminal of the first comparator and one end of the first resistor,
the first comparator outputs a first temperature detection signal from an output terminal thereof,
a k-th comparator an includes inverting input terminal connected directly to a high-potential end of a k-th resistor, k being any natural number between 1 and n, inclusive,
the k-th comparator outputs a k-th temperature detection signal from an output terminal thereof, and
the n-th resistor includes a low-potential end that is grounded.

13. A semiconductor device, comprising:
an output terminal connected to a load, and a power supply terminal connected to a power supply;
an output element connected to the output terminal and to the power supply terminal, the output element being turned on by application of a predetermined turn-on voltage to a gate of the output element in a normal state;
an overcurrent detection circuit configured to detect an overcurrent state of the output element;
a temperature detection circuit configured to detect, as a detected temperature, a temperature of the output element during an operation of the output element; and
a current limiting circuit configured to,
in response to both detecting the overcurrent state and detecting that the detected temperature is no lower than the set temperature,
set a gate voltage of the output element to a set voltage lower than the predetermined turn-on voltage, thereby limiting a current flowing through the output element, and
set the set voltage to the predetermined turn-on voltage, in response to the detected temperature having dropped to a reference temperature lower than the set temperature.

14. The semiconductor device according to claim 13, wherein
the temperature detection circuit outputs two temperature detection signals each having a first level or a second level depending on the detected temperature with respect to the set temperature and the reference temperature, and
the current limiting circuit limits the current flowing through the output element according to the two temperature detection signals.

15. The semiconductor device according to claim 14, wherein the current limiting circuit
generates a gate charge extraction signal upon receiving the two temperature detection signals indicating that the detected temperature is no lower than the set temperature, so as to extract gate charge from the gate of the output element, and
stops generating the gate charge extraction signal upon receiving the two temperature detection signals indicating that the detected temperature has dropped below the reference temperature after the temperature detection circuit has detected that the detected temperature is no lower than the set temperature, so as to stop extracting the gate charge.

16. The semiconductor device according to claim 15, wherein the current limiting circuit
generates a gate charge extraction signal upon receiving the two temperature detection signals indicating that the detected temperature is in a first temperature range defined by the detected temperature being no lower than the set temperature, or that the detected temperature is in a second temperature range defined by the detected temperature being no lower than the reference temperature and lower than the set temperature after the temperature detection circuit has detected that the detected temperature is no lower than the set temperature, so as to extract the gate charge from the gate, and
stops generating the gate charge extraction signal upon receiving the two temperature detection signals indicating that the detected temperature is in a third temperature range defined by the detected temperature is lower than the reference temperature after the temperature detection circuit has detected that the detected temperature is no lower than the set temperature, so as to stop extracting the gate charge.

17. The semiconductor device according to claim 16, wherein
the temperature detection circuit outputs, among the two temperature detection signals include a first temperature detection signal and as second temperature detection signal,
the temperature detection circuit
outputs the first and second temperature detection signals having the first level in response to detecting the detected temperature being in the first temperature range,
outputs only the second temperature detection signal having the first level in response to detecting the detected temperature being in the second temperature range, and
does not output any temperature detection signal having the first level in response to detecting the detected temperature being in the third temperature range, and
the current limiting circuit includes
a state holding circuit configured to output the gate charge extraction signal until the state holding circuit no longer receives the second temperature detection signal having the first level after the state holding circuit receives the first temperature detection signal having the first level while receiving an overcurrent detection signal that is output from the overcurrent detection circuit upon detecting the overcurrent state, and
a switch configured to conductively connect the gate to the output terminal by performing switching according to the gate charge extraction signal.

18. The semiconductor device according to claim 16, wherein
the two temperature detection signals include a first temperature detection signal and a second temperature detection signal,
the temperature detection circuit
does not output any temperature detection signal having the first level in response to detecting the detected temperature being in the first temperature range,
outputs only the second temperature detection signal having the first level in response to detecting that the detected temperature is in the second temperature range, and
outputs the first and second temperature detection signals having the first level in response to detecting that the detected temperature is in the third temperature range, and
the current limiting circuit includes
a state holding circuit configured to output the gate charge extraction signal until the state holding circuit receives the second temperature detection signal having the first level after the state holding circuit no longer receives the first temperature detection signal having the first level while receiving an overcurrent detection signal that is output from the overcurrent detection circuit upon detecting the overcurrent state, and
a switch configured to conductively connect the gate to the output terminal by performing switching according to the gate charge extraction signal.

19. The semiconductor device according to claim 14, wherein the temperature detection circuit includes
a temperature-detection constant current source configured to output a first current and a second current,
a detection circuit including a temperature sensing diode through which the first current flows, and being configured to provide a temperature detection voltage that decreases with an increase in the detected temperature,
a reference voltage generation circuit configured to provide a reference voltage, based on the second current, and
a comparison circuit configured to compare the reference voltage with the temperature detection voltage and to output the temperature detection signal having the first level upon the comparison circuit determining that the reference voltage is higher than the temperature detection voltage.

20. The semiconductor device according to claim 19, wherein
the reference voltage includes a first reference voltage and a second reference voltage lower than the first reference voltage, and
the comparison circuit
compares the first reference voltage with the temperature detection voltage, and outputs the first temperature detection signal having the first level upon determining that the first reference voltage is higher than the temperature detection voltage, and
compares the second reference voltage with the temperature detection voltage, and outputs the first temperature detection signal having the first level and the second temperature detection signal having the first level upon determining that the second reference voltage is higher than the temperature detection voltage.

21. The semiconductor device according to claim 19, wherein
the temperature-detection constant current source includes a first constant current element and a second constant current element,
the reference voltage generation circuit includes a first resistor and a second resistor, connected in series sequentially from a high potential side to a low potential side of the reference voltage generation circuit,
the comparison circuit includes a first comparator and a second comparator,
the first constant current element includes an input terminal connected to an input terminal of the second constant current element and the power supply, and an output terminal connected to an anode of the temperature sensing diode and an inverting input terminal of each of the first and second comparators, a cathode of the temperature sensing diode being grounded,
the second constant current element includes an output terminal connected to a non-inverting input terminal of the first comparator and one end of the first resistor,
the first comparator outputs, among the two temperature detection signals, a first temperature detection signal of the predetermined level from an output terminal thereof,
the second comparator includes a non-inverting input terminal connected directly to a high-potential end of the second resistor,
the second comparator outputs, among the two temperature detection signals, a second temperature detection signal of the predetermined level from an output terminal thereof, and
the second resistor includes a low-potential end that is grounded.

22. The semiconductor device according to claim 14, wherein the temperature detection circuit includes
a temperature-detection constant current source configured to output a first current and a second current,
a detection circuit including a temperature sensing diode through which the first current flows, and being configured to provide a temperature detection voltage that decreases with an increase in the detected temperature,
a reference voltage generation circuit configured to provide a reference voltage, based on the second current, and
a comparison circuit configured to compare the reference voltage with the temperature detection voltage and to output the temperature detection signal having the second level upon the comparison circuit determining that the reference voltage is higher than the temperature detection voltage.

23. The semiconductor device according to claim 22, wherein
the reference voltage includes a first reference voltage and a second reference voltage lower than the first reference voltage, and
the comparison circuit
compares the first reference voltage with the temperature detection voltage, and outputs the first temperature detection signal having the first level upon determining that the first reference voltage is higher than the temperature detection voltage, and
compares the second reference voltage with the temperature detection voltage, and outputs the first temperature detection signal having the first level and the second temperature detection signal having the first level upon determining that the second reference voltage is higher than the temperature detection voltage.

24. The semiconductor device according to claim 22, wherein
the temperature-detection constant current source includes a first constant current element and a second constant current element,
the reference voltage generation circuit includes a first resistor and a second resistor, connected in series sequentially from a high potential side to a low potential side of the reference voltage generation circuit,
the comparison circuit includes a first comparator and a second comparator,
the first constant current element includes an input terminal connected to an input terminal of the second constant current element and the power supply, and an output terminal connected to an anode of the temperature sensing diode and a non-inverting input terminal of each of the first and second comparators, a cathode of the temperature sensing diode being grounded,
the second constant current element includes an output terminal connected to an inverting input terminal of the first comparator and one end of the first resistor,
the first comparator outputs, among the two temperature detection signals, a first temperature detection signal of the predetermined level from an output terminal thereof,
the second comparator includes an inverting input terminal connected directly to a high-potential end of the second resistor,
the second comparator outputs, among the two temperature detection signals, a second temperature detection signal of the predetermined level from an output terminal thereof, and
the second resistor includes a low-potential end that is grounded.
